(19) United States
(12) Patent Application Publication
(10) Pub. No.: US 2024/0302748 A1
(43) Pub. Date: Sep. 12, 2024

(54) METHODS FOR DEPOSITING LAYERS OF MATERIALS ON SUBSTRATES AND STRUCTURES FORMED ACCORDINGLY

(71) Applicant: ASM IP Holding B.V., Almere (NL)

(72) Inventors: João Antunes Afonso, Tokyo (JP); Steaphan Mark Wallace, Leuven (BE); Paul Chatelain, Tokyo (JP); Kishan Ashokbhai Patel, Leuven (BE); Fatemeh Davodi, Helsinki (FI)

(21) Appl. No.: 18/595,105

(22) Filed: Mar. 4, 2024

Related U.S. Application Data
(60) Provisional application No. 63/488,648, filed on Mar. 6, 2023.

(51) Int. Cl. G03F 7/11; G03F 7/00

(52) U.S. Cl. CPC G03F 7/11; G03F 7/0035; G03F 7/70033; G03F 7/70041; G03F 7/70933

(57) ABSTRACT

The disclosure generally relates to the field of semiconductor substrate processing technology, and more particularly to methods for depositing layers of materials on substrates, to structures formed accordingly, and for systems for executing such methods and for forming such structures. Aspects relate to a layer deposition process comprising the steps of forming an extreme ultraviolet (EUV) photoresist underlayer on a surface of a substrate; providing a substrate within a reactor chamber; providing a precursor comprising Sn and/or In to the reactor chamber thereby adsorbing the precursor on the surface of the substrate; and forming an EUV photoresist underlayer on the surface of the substrate within the reactor chamber by exposing the precursor adsorbed on the surface to a plasma, wherein the plasma comprises H₂ as reactant and a noble gas as carrier gas.

### CROSS-REFERENCE TO RELATED APPLICATION(S)

This Application claims the benefit of U.S. Provisional Application 63/488,648 filed on Mar. 6, 2023, the entire contents of which are incorporated herein by reference.

### FIELD

The present disclosure generally relates to the field of semiconductor substrate processing technology, and more particularly to methods for depositing layers of materials onto substrates and structures formed accordingly.

### BACKGROUND

In the production of electronic devices, precise patterns and features are created on the surface of a substrate through an etching process. During these etching processes (e.g. dry and wet etching, Deep Reactive Ion Etching (DRIE), Inductively Coupled Plasma Etching (ICP)) material is removed from the surface to create the specific pattern or design. The end result is a substrate with precise and intricate features that can be used in the production of electronic devices and other products. With the need for higher densities of patterns on the substrates, there is an increased desire to form patterns and features with smaller dimensions.

Photoresist is often used to pattern a surface of a substrate prior to etching. A pattern can be formed in the photoresist by applying a layer of photoresist to a surface of the substrate, masking the surface of the photoresist, exposing the unmasked portions of the photoresist to radiation, such as ultraviolet light, developing the exposed or unexposed portions of the photoresist to remove a portion (e.g., the unmasked or masked portion) of the photoresist, while leaving a portion of the photoresist on the substrate surface.

Recently, techniques have been developed to use extreme ultraviolet (EUV) wavelengths to develop patterns having relatively small pattern features. One limitation of methods using EUV is the relatively low flux of EUV photons and the resultant long exposure times and/or the inadequate exposure of the photo-sensitive materials that are responsible for creating contrast between exposed and unexposed areas of the photoresist.

Accordingly, a need exists for structures and manufacturing methods that lower the EUV dose requirements.

### SUMMARY

The present disclosure generally relates to the field of semiconductor processing technology, and more particularly to methods for depositing layers of materials onto substrates and structures formed accordingly.

The present disclosure relates to a layer deposition process and structures prepared accordingly which were found to considerably reduce the dose of photoresist exposure required during EUV lithography. By providing EUV photoresist underlayers which comprise Sn and/or In dopants, and in particular Sn(0) and/or In(0) dopants, the required dose for exposure of the photoresist could be reduced with about 5% or more and this while maintaining an excellent roughness. The present disclosure therefore provides for methods and systems for preparing layered structures that comprise an EUV photoresist underlayer on the surface of the substrate and which comprises a dopant selected from Sn, In or an alloy thereof and in particular Sn(0), In(0), SnOx, InOx or an alloy thereof.

A first overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims.

An aspect of the present disclosure relates to a layer deposition process comprising the step of forming an extreme ultraviolet (EUV) photoresist underlayer on a surface of a substrate, the method comprising the steps of:
providing a substrate within a reactor chamber;
providing a precursor comprising Sn and/or In to said reactor chamber thereby adsorbing said precursor on the surface of said substrate; and
forming an EUV photoresist underlayer on the surface of the substrate within the reaction chamber by exposing the precursor adsorbed on the surface to a plasma,
   wherein the plasma comprises H₂ as reactant and a noble gas as carrier gas.

In some embodiments the layer deposition process as disclosed herein provides that the reactor chamber is purged before and after exposing the precursor deposited on the surface of said substrate to said plasma.

In some embodiments the layer deposition process as disclosed herein provides that the method for forming the EUV photoresist underlayer comprises the subsequent steps of:
(i) providing a substrate within a reactor chamber;
(ii) providing a precursor comprising Sn and/or In to said reactor chamber thereby adsorbing said precursor on the surface of said substrate;
(iii) optionally purging said reactor chamber;
(iv) exposing the precursor adsorbed on the surface to a plasma comprising H₂ as reactant and a noble gas as carrier gas, thereby forming an underlayer film on said surface; and
(v) optionally purging said reactor chamber;
wherein steps (ii) to (v) are repeated until the underlayer constituted by the films has a desired thickness.

In some embodiments the layer deposition process as disclosed herein provides that the EUV photoresist underlayer comprises a dopant selected from Sn, In or an alloy thereof, and preferably a dopant selected from Sn(0), In(0), SnOx, InOx or an alloy thereof, more preferably Sn(0), In(0) or an alloy thereof.

In some embodiments the layer deposition process as disclosed herein provides that the noble gas is chosen from He, Ne, Ar, Kr and Xe, and preferably Ar or He.

In some embodiments the layer deposition process as disclosed herein provides that the precursor is a Sn(R₁)₄ compound wherein R₁ is a halogen, a C₂-C₆ alkenyl, a C₁ to C₆ alkyl or —NR₂R₃, with R₂ and R₃ being independently selected from the group comprising C₁ to C₆ alkyls. More in particular the halogen is Cl, the C₂-C₆ alkenyl is vinyl or allyl, the C₁ to C₆ alkyl is a butyl or R₂ and R₃ being independently selected from C₁, C₂ or C₃ alkyls.

In some embodiments the layer deposition process as disclosed herein provides that the precursor is chosen from tin tetrachloride, tetra(dimethlyamino)tin, tetra(diethlyamino)tin, tetra(ethyl(methyl)amino)tin, tetravinyltin, tetraallyltin and/or tetrabutyltin.

In some embodiments the layer deposition process as disclosed herein provides that the precursor is a In(R₁)₃ compound wherein R₁ is a halogen, a C₂-C₆ alkenyl, or a C₁ to C₆ alkyl. More in particular the halogen is Cl, the C₂-C₆ alkenyl is vinyl or allyl, or the C₁ to C₆ alkyl being C₁, C₂, C₃ or C₄ alkyls.

In some embodiments the layer deposition process as disclosed herein provides that the precursor is chosen from indium chloride, triethenylindium, tri(allyl)indium, trimethylindium, triethylindium, tripropylindium, triisopropylindium, tributylindium and/or triisobutylindium.

In some embodiments the layer deposition process as disclosed herein further comprises a step of forming an EUV photoresist layer overlying the EUV photoresist underlayer. More in particular the layer deposition process as disclosed herein further comprises a step of forming a glue layer overlying the EUV photoresist underlayer.

In some embodiments the layer deposition process as disclosed herein provides that the layer deposition process comprises the post-treatment of the EUV photoresist underlayer by exposing the EUV photoresist underlayer to a plasma comprising H₂ as reactant and a noble gas, preferably Ar or He, as carrier gas.

In some embodiments the layer deposition process as disclosed herein provides that the plasma exposure occurs in a pulsed manner.

Another aspect of the present disclosure relates to a structure for forming patterned features using EUV radiation, the structure comprising a substrate and an EUV photoresist underlayer overlying the substrate, wherein the EUV photoresist underlayer comprises a dopant selected from Sn, In or an alloy thereof.

In some embodiments the structure as disclosed herein provides that the dopant is selected from Sn(0), In(0), SnOx, InOx or an alloy thereof, more in particular Sn(0), In(0) or an alloy thereof.

In some embodiments the structure as disclosed herein provides that the dopant is present in the EUV photoresist underlayer is present in an amount of at least 1.0 atomic percent.

In some embodiments the structure as disclosed herein provides that the thickness of the EUV photoresist underlayer ranges between 1.0 nm and 50.0 nm.

In some embodiments the structure as disclosed herein provides that the EUV photoresist underlayer is a laminated layer.

In some embodiments the structure as disclosed herein further comprises an EUV photoresist layer overlying the EUV photoresist underlayer. More particularly, the structure as disclosed herein further comprises a glue layer between the EUV photoresist layer and the EUV photoresist underlayer.

Another aspect of the present disclosure relates to a system comprising a reaction chamber, a precursor source, a reactant source, and a controller, the system being constructed and arranged for carrying out the process as disclosed herein.

### BRIEF DESCRIPTION OF THE FIGURES

The following description of the figures relate to specific embodiments of the disclosure which are merely exemplary in nature and not intended to limit the present teachings, their application or uses.

Throughout the drawings, the corresponding reference numerals indicate the following parts and features: layer deposition process 1; providing substrate to the reaction chamber 2; providing precursor to the reaction chamber 3; exposing precursor adsorbed on the surface to plasma 4; forming EUV photoresist underlayer 5; cyclic repeat 6; forming EUV photoresist layer overlying the EUV photoresist underlayer 7; precursor 8; plasma 9; structure 10; substrate 11; EUV photoresist under layer 12; photoresist layer 13; glue 14; system 100; reaction chamber 101; precursor injector system 102; reactant injector system 103; reaction chamber 110; reaction chamber 111; precursor vessel 112; reactant vessel 113; plasma unit 123; exhaust source 130; and controller 150.

FIG. 1 illustrates a method in accordance with exemplary embodiments of the disclosure.

FIGS. 2A and 2B each illustrate a structure in accordance with exemplary embodiments of the disclosure.

FIG. 3 illustrates a system in accordance with exemplary embodiments of the disclosure.

FIG. 4 shows the results of experiments with structures in accordance with exemplary embodiments of the disclosure.

### DETAILED DESCRIPTION

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

The present disclosure relates to a layer deposition process and structures prepared accordingly which were found to considerably reduce the dose of photoresist exposure required during EUV lithography. While the present disclosure is described in terms of the layer depositing process, it will be appreciated that any method or system for EUV lithography can benefit from the present technology.

By providing EUV photoresist underlayers which comprise Sn and/or In dopants, and in particular Sn(0) and/or In(0) dopants, the required dose for exposure of the photoresist could be reduced with about 5% or more and this while maintaining an excellent roughness. It shall be understood that Sn(0) refers to tin in oxidation state 0, i.e. to metallic tin. Similarly, it shall be understood that In(0) refers to indium in oxidation state 0, i.e. to metallic indium.

The present disclosure therefore provides for methods and systems for preparing layered structures that comprise an EUV photoresist underlayer on the surface of the substrate and which comprises a dopant selected from Sn, In or an alloy thereof.

An overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure. When describing specific embodiments, reference is made to the accompanying drawings, which are provided solely to aid in the understanding of the described embodiment.

An aspect of the present disclosure relates to a layer deposition process comprising the step of forming an extreme ultraviolet (EUV) photoresist underlayer on a surface of a substrate, the method comprising the steps of:
providing a substrate within a reactor chamber;
providing a precursor comprising Sn and/or In to said reactor chamber thereby adsorbing said precursor on the surface of said substrate; and
forming an EUV photoresist underlayer on the surface of the substrate within the reaction chamber by exposing the precursor adsorbed on the surface to a plasma, wherein the plasma comprises H₂ as reactant and a noble gas as carrier gas.

As used herein, the term “substrate” may refer to any supporting material upon which or within which the elements of a semiconductor device are fabricated or attached. The supporting material may be a layer of semiconductor material cut from a single crystal, a layer of semiconductor material deposited on a supporting base, or the supporting base itself. The substrate may be a wafer made from a semiconductor material, for example, a crystalline silicon wafer. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can additionally or alternatively include various features, such as recesses, lines, and the like formed within or on at least a portion of a layer of the substrate.

In the process as disclosed herein an EUV photoresist underlayer is formed on the surface of the substrate. As disclosed herein, “EUV photoresist underlayer” refers to a particular layer that extends in a perpendicular direction over the surface of the substrate being characterized by having a certain thickness. The EUV photoresist underlayer is positioned between the photoresist layer and the substrate and has been found to be able to considerably reduce the dose required for exposure of the photoresist. Compared to structures where the photoresist is deposited onto the substrate in the absence of a EUV photoresist underlayer the required EUV dose is reduced with at least 5%.

In some embodiments the layer deposition process as disclosed herein provides that the method for forming the EUV photoresist underlayer comprises the subsequent steps of:
(i) providing a substrate within a reactor chamber;
(ii) providing a precursor comprising Sn and/or In to said reactor chamber thereby adsorbing said precursor on the surface of said substrate;
(iii) optionally purging said reactor chamber;
(iv) exposing the precursor adsorbed on the surface to a plasma comprising H₂ as reactant and a noble gas as carrier gas, thereby forming an underlayer film on said surface; and
(v) optionally purging said reactor chamber;
wherein steps (ii) to (v) are repeated until the underlayer constituted by the films has a desired thickness. Purging steps (iii) and (v) are optional. While purging may be a standard step in a PEALD process, the omission of a purge step may help to increase the throughput.

As used herein the term “film” refers to a layer extending in a direction perpendicular. Whereas a film typically refers to a discrete single film having certain characteristics, a layer of underlayer is formed by multiple stacked films. The boundary between adjacent films may not be clear.

In a particular embodiment step (iv) is a single pulse of plasma or step (iv) are multiple pulses of plasma. Multiple plasma pulses in particular refers to a sequence of plasma on/plasma off steps.

In some embodiments the layer deposition process as disclosed herein provides that the EUV photoresist underlayer comprises a dopant selected from Sn, In or an alloy thereof, and preferably a dopant selected from Sn(0), In(0), SnOx, InOx or an alloy thereof, more preferably Sn(0), In(0) or an alloy thereof. More in particular the dopant is present in the EUV photoresist underlayer in an amount of at least 1.0 atomic percent (atomic percent provides the percentage of one kind of atom relative to the total number of atoms).

In some embodiments the layer deposition process as disclosed herein further comprises a step of forming an EUV photoresist layer overlying the EUV photoresist underlayer. More in particular the layer deposition process as disclosed herein further comprises a step of forming a glue layer overlying the EUV photoresist underlayer. The glue gayer may improve the adherence of the EUV photoresist layer. The glue layer may for instance be an SiARC (silicon oxycarbide —SiOC—a non-stoichiometric amorphous material substantially consisting of Si, O, C, and H) film that is used as a glue layer for photoresist. SiARC is silicon-containing anti reflective coating.

In some embodiments the layer deposition process as disclosed herein provides that the layer deposition process comprises the post-treatment of the EUV photoresist underlayer by exposing the EUV photoresist underlayer to a plasma comprising H₂ as reactant and a noble gas, preferably Ar or He, as carrier gas. This post-treatment has been shown to provide a dose reduction compared to untreated material.

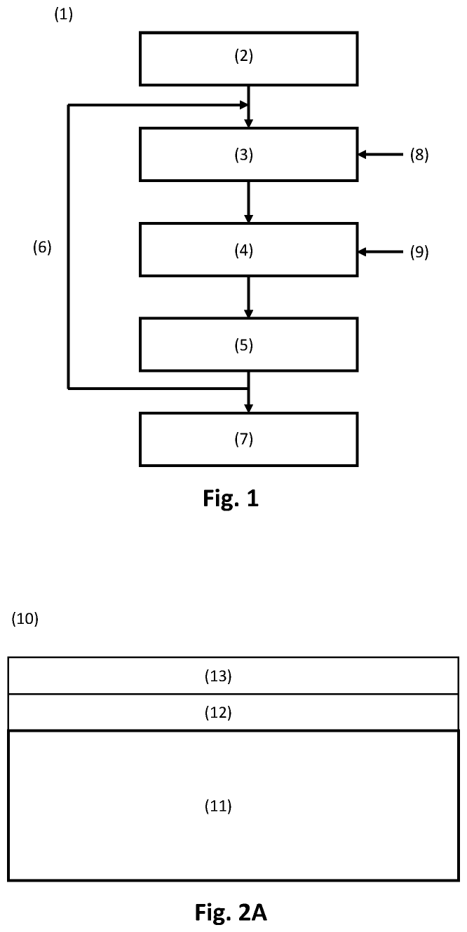

FIG. 1 is a flow diagram of a layer deposition process (1) for preparing a structure in accordance with aspects of the present disclosure. It is understood that additional steps can be provided before, during, and after the steps of the process as disclosed herein.

In the shown embodiment, the layer deposition process (1) can be used for forming an extreme ultraviolet (EUV) photoresist underlayer on a surface of a substrate which includes the steps of providing a substrate within a reaction chamber (step 2), providing a precursor (8) to the reaction chamber (step 3) thereby adsorbing said precursor on the surface of said substrate, exposing (step 4) the precursor adsorbed on the surface to a plasma (9) thereby forming an EUV photoresist underlayer (step 5) on the surface of the substrate within the reaction chamber. The process (1) is conducted in a cyclic manner wherein process steps 3, 4 and 5 are cyclically repeated (step 6) one or more times thereby growing and forming the EUV photoresist underlayer. The cyclic process is repeated until the EUV photoresist underlayer has reached the desired thickness. Steps 3, 4 and 5 may be performed contemporaneously in some desirable implementations of the process (1) and/or in differing orders. For example, the steps of exposing the substrate to precursor and plasma may be performed either in an alternating or simultaneous manner, and this results in EUV photoresist underlayer formation occurring contemporaneously with precursor and plasma exposure.

The process (1) can also further include a step of purging the reactor chamber before and after step 4. As used herein, the term purge or purging may refer to a procedure in which gas flow is stopped or a procedure involving continual provision of a carrier gas whereas precursor flow is intermittently stopped. For example, a purge may be provided between a precursor pulse and a plasma pulse, thus avoiding, or at least reducing, gas phase interactions between the precursor and the plasma. It shall be understood that a purge can be affected either in time or in space or both. For example, in the case of temporal purges, a purge step can be used, e.g., in the temporal sequence of providing a precursor to a reactor chamber, providing a purge gas to the reactor chamber, and providing a plasma to the reactor chamber, wherein the substrate on which a layer is deposited does not move. In the case of spatial purges, a purge step can take the form of moving a substrate from a first location to which a precursor is supplied, through a purge gas curtain, to a second location to which a plasma is supplied.

The process (1) can also further include a step of forming an EUV photoresist layer (step 7) overlying the EUV photoresist underlayer.

Step 2 includes providing a substrate, such as a substrate described herein, within a reaction chamber. The substrate can include one or more layers, including one or more material layers, to be etched. By way of examples, the substrate can include a deposited oxide, a native oxide, or an amorphous carbon layer to be etched. The substrate can include several layers underlying the material layer(s) to be etched.

During step 3, a precursor (8) comprising Sn and/or In is provided to the reaction chamber and is chemisorbed to a surface of the substate.

Exemplary precursors comprising Sn can include a Sn(R₁)₄ compound wherein R₁ is a halogen, a C₂-C₆ alkenyl, a C₁ to C₆ alkyl or —NR₂R₃, with R₂ and R₃ being independently selected from the group comprising C₁ to C₆ alkyls. More in particular the halogen is Cl, the C₂-C₆ alkenyl is vinyl or allyl, the C₁ to C₆ alkyl is a methyl, ethyl, propyl, isopropyl or butyl, or R₂ and R₃ being independently selected from C₁, C₂ or C₃ alkyls. More in particular the precursor comprising Sn is chosen from tin tetrachloride, tetramethlytin, tetraethlytin, tetrapropyltin, tetraisopropyltin, tetra(dimethlyamino)tin, tetra(diethlyamino)tin, tetra(ethyl(methyl)amino)tin, tetravinyltin, tetraallyltin and/or tetrabutyltin.

In some embodiment the precursor comprising Sn is a homoleptic or heteroleptic precursor.

Exemplary precursors comprising In can include a In(R₁)₃ compound wherein R₁ is a halogen, a C₂-C₆ alkenyl, or a C₁ to C₆ alkyl. More in particular the halogen is Cl, the C₂-C₆ alkenyl is vinyl or allyl, or the C₁ to C₆ alkyl being C₁, C₂, C₃ or C₄ alkyls. More in particular the precursor comprising In is chosen from indium chloride, triethenylindium, tri(allyl)indium, trimethylindium, triethylindium, tripropylindium, triisopropylindium, tributylindium and/or triisobutylindium.

In some embodiment the precursor comprising In is a homoleptic or heteroleptic precursor.

During step 3 the temperature within the reaction chamber can be, for example, between about 50° C. and about 300° C. depending on the type of precursor used, the pressure within the reaction chamber can be, for example, between about 150 Pa to about 1000 Pa, the flowrate of the precursor can be, for example, between about 250 to about 2000 mL/min. The duration of the pulse of introducing the precursor to the reaction chamber can be between about 0.1 and about 30 seconds.

During step 4, a plasma (9) is provided to the reaction chamber. In accordance with examples of the disclosure, the plasma comprises H₂ as reactant and a noble gas as carrier gas. More in particular the noble gas is chosen from He, Ne, Ar, Kr and Xe, and is preferably Ar or He.

The reaction conditions (temperature and pressure) within the reaction chamber during step 4 can be the same or similar to the reaction conditions noted above in connection with step 3. A flowrate of the plasma can be, for example, between about 250 to about 3000 mL/min. A duration of a pulse of introducing the plasma to the reaction chamber can be between about 0.1 and about 30 seconds.

Whereas the most prominent results were observed when the precursor was exposed to a plasma that comprises H₂ as reactant and Ar or He as carrier gas, it should be noted that also other plasmas (Ar, Ar/He and/or Ar/O₂) can be used to form an EUV photoresist underlayer. However the reduced dose exposure of the photoresist was not observed for these other plasmas.

In some embodiments the layer deposition process as disclosed herein provides that the plasma exposure occurs in a pulsed manner. The plasma pulsations may be single or multiple pulses at a frequency between 0.1 and 100 Hz, more particularly between 0.5 and 50 Hz and preferably between 1 and 10 Hz.

The EUV photoresist underlayer described herein is be formed using processing techniques such as atomic layer deposition (ALD), cyclical chemical vapor deposition (cyclical CVD), and hybrid cyclical deposition processes that include an ALD component and a cyclical CVD component and in particular a plasma process such as plasma enhanced CVD (PECVD) or plasma enhanced ALD (PEALD).

The term atomic layer deposition refers to a vapor deposition process in which deposition cycles are conducted in a reactor chamber. The term atomic layer deposition, as used herein, is meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, a reactant is introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

Another aspect of the present disclosure relates to a structure for forming patterned features using EUV radiation, the structure comprising a substrate and an EUV photoresist underlayer overlying the substrate, wherein the EUV photoresist underlayer comprises a dopant selected from Sn, In or an alloy thereof.

In some embodiments the structure as disclosed herein provides that the dopant is selected from Sn(0), In(0), SnOx, InOx or an alloy thereof, more in particular Sn(0), In(0) or an alloy thereof.

In some embodiments the structure as disclosed herein provides that the dopant is present in the EUV photoresist underlayer is present in an amount of at least 1.0 atomic percent.

In some embodiments the structure as disclosed herein provides that the thickness of the EUV photoresist underlayer ranges between 1.0 nm and 50.0 nm, more in particular between 1.5 nm and 25 nm, and preferably between 2.0 and 15 nm.

In some embodiments the structure as disclosed herein provides that the EUV photoresist underlayer is a laminated layer.

In some embodiments the structure as disclosed herein further comprises an EUV photoresist layer overlying the EUV photoresist underlayer. More particularly, the structure as disclosed herein further comprises a glue layer between the EUV photoresist layer and the EUV photoresist underlayer.

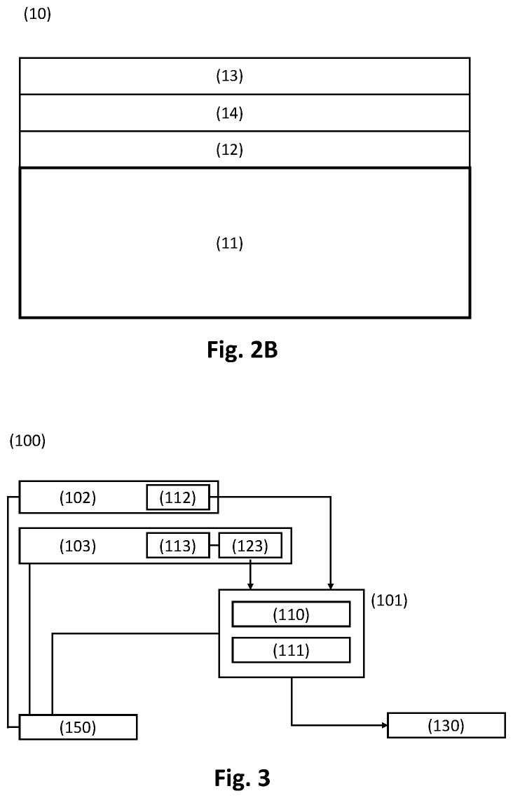

FIG. 2A illustrates a structure 10 in accordance with exemplary embodiments of the disclosure. Structure 10 can be formed using, for example, the process (1) as indicated herein. As illustrated, structure 10 includes a substrate 11 and an EUV photoresist underlayer 12, and optionally a photoresist layer 13.

FIG. 2B illustrates a structure 10 in accordance with exemplary embodiments of the disclosure. Structure 10 can be formed using, for example, the process (1) as indicated herein. As illustrated, structure 10 includes a substrate 11 and an EUV photoresist underlayer 12, and optionally one or more of a photoresist layer 13, and a glue layer 14 between said EUV photoresist underlayer 12 and said photoresist layer 13.

The substrate 11 can include a substrate as described above. By way of examples, substrate 11 can include a semiconductor substrate and can include one or more layers. Further, as noted above, substrate 11 can include various topologies, such as recesses, lines, and the like formed within or on at least a portion of a layer of the substrate.

The EUV photoresist underlayer 12 include a layer formed in accordance with the process described herein (e.g., process 1) and/or comprises a dopant selected from Sn, In or an alloy thereof. The thickness of EUV photoresist underlayer 12 depends on the composition of the EUV photoresist underlayer 12, the thickness of and/or composition of the photoresist layer 13, the type of photoresist, and the like. In accordance with examples of the disclosure, the thickness of the EUV photoresist underlayer 12 ranges between 1.0 nm and 50.0 nm, more in particular between 2.5 nm and 25 nm, and preferably between 5.0 and 15 nm.

It is further noted that the EUV photoresist underlayer 12 may be deposited on a material layer formed of, for example, a hard mask. A hard mask can be any layer that provides etch contrast with the underlying layers. One possible hard mask is amorphous carbon. In other embodiments, the material layer may include metals, semiconductors and their alloys, oxides, nitrides, and carbides. A thickness of material layer can be from about 0.1 to about 10 nm. Photoresist layer 13 can be formed of, for example, a molecular resist, a metal oxide resist, or a chemically amplified resist. The thickness of the photoresist layer 13 can be from about 5 to about 40 nm.

Another aspect of the present disclosure relates to a system comprising a reaction chamber, a precursor source, a reactant source, and a controller, the system being constructed and arranged for carrying out the process as disclosed herein.

The system as disclosed herein may further comprise a substrate handler system and a substate report system.

It is understood, based on any of the embodiments described herein, that the herein disclosed method can be performed by the herein disclosed system. That is, the hardware or software of the system can be adapted in a way that it can perform the method and any steps thereof, and vice versa, even if not explicitly described as such.

The processor of the controller may include any one or more of a microprocessor, a controller, a digital signal processor (DSP), an application specific integrated circuit (ASIC), a field-programmable gate array (FPGA), or equivalent discrete or integrated logic circuitry. In some embodiments, the controller is a computer system. The processor may be connected to the memory, transmitter, and receiver.

The memory of the controller may be a semiconductor memory such as, for example, read-only memory, a random access memory, a FRAM, or a NAND flash memory. The memory may interface with the processor and associated processors such that the processor may write to and read from the memory.

In some embodiments the controller can be connected to a display device for viewing the progress of the process that is carried out in the system as disclosed herein.

FIG. 3 schematically illustrates a system 100 in accordance with examples of the disclosure. System 100 can be used to perform a method as described herein and/or to form a structure or a portion thereof as described herein. In the illustrated example, system 100 includes one or more reaction chambers 101 (110 and 111), a precursor injector system 102 comprising a precursor vessel 112, a reactant injector system 103 comprising a reactant vessel 113 and a plasma unit 123, an exhaust source 130, and a controller 150. In some cases, though, it will be understood that some reactants, such as O₂, N₂ and H₂, are very common and are used throughout a fabrication. Accordingly, they may not be necessarily stored in a vessel inside the tool but may, instead, be provided from a central storage unit (not shown, which may be a pressurized vessel) via gas lines to the tools in the fabrication system 100. System 100 may include one or more additional gas sources (not shown), such as an inert gas source, a carrier gas source and/or a purge gas source. Reaction chamber 101 can include any suitable reaction chamber, such as an PEALD or PECVD reaction chamber as described herein.

Precursor vessel 112 can include a vessel and one or more precursors as described herein alone or mixed with one or more carrier (e.g., inert) gases. Reactant vessel 113 can include a vessel and one or more reactants as described herein alone or mixed with one or more carrier gases. Plasma unit 123 activates the one or more reactants prior to them entering into the reaction chamber 101. Although illustrated with two source vessels 112 and 113, system 100 can include any suitable number of source vessels to provide the element with a high EUV absorption on a per mass basis and other materials, such as doping materials, in some implementations. Source vessels 112 and 113 are coupled to the reaction chamber 101 via flow lines which can each include flow controllers, valves, heaters, and the like. In some embodiments, a vessel is heated so that a precursor or a reactant reaches a desired temperature. Each vessel may be heated to a different temperature, according to the precursor or reactant properties, such as thermal stability and volatility. Exhaust source 130 can include one or more vacuum pumps.

Controller 150 includes electronic circuitry and software to selectively operate valves, manifolds, heaters, pumps, and other components included in system 100. Such circuitry and components operate to introduce precursors, reactants, and purge gases from the respective sources. Controller 150 can control timing of gas pulse sequences, temperature of the substrate and/or reaction chamber 101, pressure within the reaction chamber 101, and various other operations to provide proper operation of the deposition or reactor system 100. Controller 150 can include control software to electrically or pneumatically control valves to control flow of precursors, reactants, and purge gases into and out of the reaction chamber 101. Controller 150 can include modules, such as a software or hardware component, which perform certain tasks. A module may be configured to reside on the addressable storage medium of the control system and be configured to execute one or more processes.

Other configurations of system 100 are possible, including different numbers and kinds of precursor and reactant sources. Further, it will be appreciated that there are many arrangements of valves, conduits, precursor sources, and auxiliary reactant sources that may be used to accomplish the goal of selectively and in a coordinated manner feeding gases into reaction chamber 101. Further, as a schematic representation of a deposition system, many components have been omitted for simplicity of illustration, and such components may include, for example, various valves, manifolds, purifiers, heaters, containers, vents, and/or bypasses.

During operation of deposition assembly 100, substrates, such as semiconductor wafers, are transferred from, for example, a substrate handling system to reaction chamber 101. Once substrates are transferred to reaction chamber 101, one or more gases from gas sources, such as precursors, reactants, carrier gases, and/or purge gases, are introduced into reaction chamber 101. In some embodiments, the precursor is supplied in pulses, the reactant is supplied in pulses and the reaction chamber is purged between consecutive pulses of precursor and reactant.

As used herein, the terms “one embodiment” or “an embodiment” means that a particular feature, structure or characteristic described in connection with the embodiment is included in at least one embodiment of the present disclosure. Thus, appearances of the phrases “in some embodiments” in various places throughout this specification are not necessarily all referring to the same embodiments.

As used herein, the terms “comprising”, “comprises” and “comprised of” are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” said recited members, elements or method steps. The singular forms “a”, “an”, and “the” include both singular and plural referents unless the context clearly dictates otherwise.

As used herein, the terms “connected” or “coupled” reflect a functional relationship between the described objects or devices, that is, the terms indicate the described objects must be connected in a way to perform a designated function which may include a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all numbers and fractions subsumed within the respective ranges, as well as the recited endpoints. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

As used herein, the term “improved” with reference to the performance of devices or objects is a measure of a benefit obtained based on a comparison to similar devices or objects in the prior art. Furthermore, it is to be understood that the degree of improved performance may vary between disclosed embodiments and that no equality or consistency in the amount, degree, or realization of improved performance is to be assumed as universally applicable.

### EXAMPLES

A contrast curve experiment was performed where the thickness of a photoresist layer was tested after different doses of EUV exposure. A structures as shown in FIG. 2A were prepared using the same photoresist layer but with different EUV photoresist underlayers on the surface of the substrate. The samples in the experiment were deposited at the same time, in the same deposition tool but using different materials. Structures A and C comprise EUV photoresist underlayers comprising tin oxycarbide, with the photoresist underlayer of structure A having been subjected to an Ar plasma exposure, and the photoresist underlayer of structure C having been subjected to an Ar/H₂ plasma exposure. Structure B comprises EUV photoresist underlayer comprising silicon oxycarbide on the surface of the substrate that was subjected to a Ar/H₂ plasma exposure. The Ar/H₂ plasma exposure for structure C resulted in the EUV photoresist underlayer comprising reduced Sn.

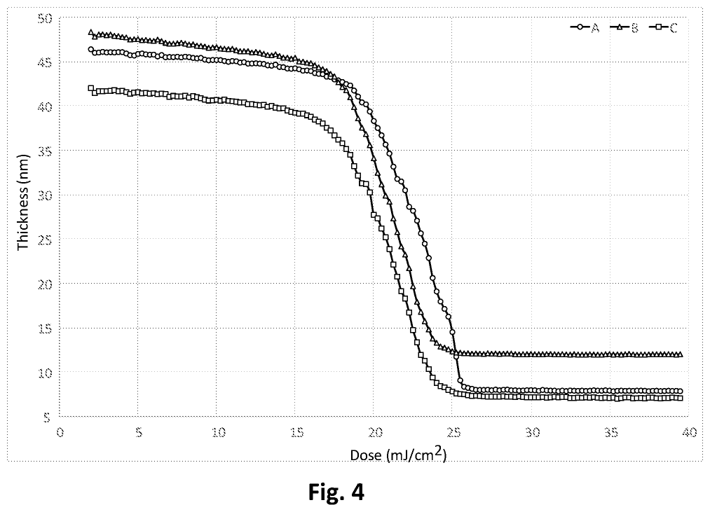

FIG. 4 shows the results of the experiment. As can be seen from the graph, the EUV exposure required for a structure (A) having a normal EUV photoresist layer is higher when compared to the EUV exposure required for a structure (C) where the EUV photoresist layer further comprises an EUV photoresist underlayer according to the present invention. In addition, a structure (B) that comprises a glue (ULX) layer under a normal EUV photoresist layer also requires a higher dose.

1. A layer deposition process comprising the steps of:
forming an extreme ultraviolet (EUV) photoresist underlayer on a surface of a substrate;
providing a substrate within a reactor chamber;
providing a precursor comprising Sn and/or In to the reactor chamber thereby adsorbing the precursor on the surface of the substrate; and
forming an EUV photoresist underlayer on the surface of the substrate within the reactor chamber by exposing the precursor adsorbed on the surface to a plasma,
wherein the plasma comprises H₂ as reactant and a noble gas as carrier gas.

2. The layer deposition process according to claim 1, wherein the reactor chamber is purged before and after exposing the precursor adsorbed on the surface of the substrate to the plasma.

3. The layer deposition process according to claim 1, wherein the forming the EUV photoresist underlayer comprises the subsequent steps of:
(i) providing a substrate within a reactor chamber;
(ii) providing a precursor to the reactor chamber thereby adsorbing said precursor on the surface of the substrate;
(iii) exposing the precursor adsorbed on the surface to a plasma comprising H₂ as reactant and a noble gas as carrier gas, thereby forming an underlayer film on the surface; and
wherein steps (ii) to (iii) are repeated until the underlayer constituted by the films has a desired thickness.

4. The layer deposition process according to claim 1, wherein the EUV photoresist underlayer comprises a dopant selected from Sn, In or an alloy thereof.

5. The layer deposition process according to claim 1, wherein the noble gas is chosen from He, Ne, Ar, Kr and Xe.

6. The layer deposition process according to claim 1, wherein the precursor is a Sn(R₁)₄ compound wherein R₁ is a halogen, a C₂-C₆ alkenyl, a C₁ to C₆ alkyl or —NR₂R₃, with R₂ and R₃ being independently selected from the group comprising C₁ to C₆ alkyls.

7. The layer deposition process according to claim 6, wherein the halogen is Cl, the C₂-C₆ alkenyl is vinyl or allyl, the C₁ to C₆ alkyl is a butyl or R₂ and R₃ being independently selected from C₁, C₂ or C₃ alkyls.

8. The layer deposition process according to claim 1, wherein the precursor is chosen from tin tetrachloride, tetra(dimethlyamino)tin, tetra(diethlyamino)tin, tetra(ethyl(methyl)amino)tin, tetravinyltin, tetraallyltin and/or tetrabutyltin.

9. The layer deposition process according to claim 1, wherein the precursor is a In(R₁)₃ compound wherein R₁ is a halogen, a C₂-C₆ alkenyl, or a C₁ to C₆ alkyl.

10. The layer deposition process according to claim 9, wherein the halogen is Cl, the C₂-C₆ alkenyl is vinyl or allyl, or the C₁ to C₆ alkyl being C₁, C₂, C₃ or C₄ alkyls.

11. The layer deposition process according to claim 1, wherein the precursor is chosen from indium chloride, triethenylindium, tri(allyl)indium, trimethylindium, triethylindium, tripropylindium, triisopropylindium, tributylindium and/or triisobutylindium.

12. The layer deposition process according to claim 1, further comprising a step of forming an EUV photoresist layer overlying the EUV photoresist underlayer.

13. The layer deposition process according to claim 1, further comprising a step of forming a glue layer overlying the EUV photoresist underlayer.

14. The layer deposition process according to claim 1, wherein the layer deposition process comprises post-treatment of the EUV photoresist underlayer by exposing the EUV photoresist underlayer to a plasma comprising H₂ as reactant and a noble gas as carrier gas.

15. The layer deposition process according to claim 14, wherein the plasma exposure occurs in a pulsed manner.

16. A structure for forming patterned features using EUV radiation, the structure comprising:
a substrate; and
an EUV photoresist underlayer overlying the substrate, wherein the EUV photoresist underlayer comprises a dopant selected from Sn, In or an alloy thereof.

17. The structure according to claim 16, wherein the dopant is selected from Sn(0), In(0), SnOx, InOx or an alloy thereof.

18. The structure according to claim 16, wherein the dopant is present in the EUV photoresist underlayer in an amount of at least 1.0 atomic percent.

19. The structure according to claim 16, wherein thickness of the EUV photoresist underlayer ranges between 1.0 nm and 50.0 nm.

20. The structure according to claim 16, wherein the EUV photoresist underlayer is a laminated layer.

21. The structure according to claim 16, further comprising an EUV photoresist layer overlying the EUV photoresist underlayer.

22. The structure according to claim 21, further comprising a glue layer between the EUV photoresist layer and the EUV photoresist underlayer.

23. A system comprising a reactor chamber, a precursor source, a reactant source, and a controller, the system being constructed and arranged for carrying out a layer deposition process comprising the steps of
forming an extreme ultraviolet (EUV) photoresist underlayer on a surface of a substrate providing a substrate within the reactor chamber;
providing a precursor comprising Sn and/or In to the reactor chamber thereby adsorbing the precursor on the surface of the substrate; and
forming an EUV photoresist underlayer on the surface of the substrate within the reactor chamber by exposing the precursor adsorbed on the surface of the substrate to a plasma,
wherein the plasma comprises H₂ as reactant and a noble gas as carrier gas.
